(19) United States
(12) Patent Application Publication
(10) Pub. No.: US 2025/0130285 A1
(43) Pub. Date: Apr. 24, 2025

(54) DETECTION DEVICE FOR DETECTING SIGN OF THERMAL RUNAWAY FOR SECONDARY BATTERY AND METHOD FOR DETECTING SIGN OF THERMAL RUNAWAY FOR SECONDARY BATTERY

(71) Applicant: DENSO CORPORATION, Kariya-city (JP)

(72) Inventors: Shuhei YOSHIDA, Kariya-city (JP); Yuji YAMAGAMI, Kariya-city (JP)

(21) Appl. No.: 19/007,467

(22) Filed: Dec. 31, 2024

Related U.S. Application Data
(63) Continuation of application No. PCT/JP2023/024741, filed on Jul. 4, 2023.

(30) Foreign Application Priority Data
Jul. 12, 2022 (JP) 2022-111981

(51) Int. Cl. G01R 31/389; G01R 31/36; G01R 31/367; G01R 31/374; G01R 31/3842; G01R 31/392

(52) U.S. Cl. CPC G01R 31/389; G01R 31/3648; G01R 31/367; G01R 31/374; G01R 31/3842; G01R 31/392

(57) ABSTRACT

A thermal runaway sign detection device includes a measurement unit that measures a voltage fluctuation in a first mode in which a number of times that a fluctuating current is output from the secondary battery and voltage fluctuation of the secondary battery in response to the fluctuating current is measured is first number of times, and in a second mode in which the number of times is second number of times less than the first number of times. A detection unit detects a sign of thermal runaway in the secondary battery when a rate of change in a real part of an AC impedance obtained based on the voltage fluctuation measured by the measurement unit at the fluctuating current of a predetermined frequency at which an imaginary part of the AC impedance of the secondary battery calculated based on the voltage fluctuation becomes zero, is greater than a threshold value.

### CROSS REFERENCE TO RELATED APPLICATIONS

This application is a continuation application of International Patent Application No. PCT/JP2023/024741 filed on Jul. 4, 2023, which designated the U.S. and based on and claims the benefits of priority of Japanese Patent Application No. 2022-111981 filed on Jul. 12, 2022. The entire disclosure of all of the above applications is incorporated herein by reference.

### TECHNICAL FIELD

The present disclosure relates to a detection device for detecting a sign of thermal runaway in a secondary battery.

### BACKGROUND ART

Conventionally, a device may measure a complex independence of a secondary battery for multiple frequencies within a measurement range and create a complex impedance plane plot, for example, Cole-Cole plot or Bode plot based on the measurement result to understand the properties of the secondary battery such as an electrode and electrolyte of the second battery.

### SUMMARY

A main object of the present disclosure is to detect a sign of thermal runaway while suppressing power consumption of a secondary battery.

According to a first aspect to address the above-mentioned issue,
a thermal runaway sign detection device for detecting a sign of thermal runaway in a secondary battery includes
a measurement unit that measures a voltage fluctuation in a first mode in which a number of times that a fluctuating current is output from the secondary battery and a voltage fluctuation of the secondary battery in response to the fluctuating current is measured is a first number of times, and in a second mode in which the number of times is a second number of times less than the first number of times,
a switching unit that switches the measurement unit to the second mode when the secondary battery is stopped, and
a detection unit that detects a sign of thermal runaway in the secondary battery when a rate of change in a real part of an AC impedance obtained based on the voltage fluctuation measured by the measurement unit at the fluctuating current of a predetermined frequency at which an imaginary part of the AC impedance of the secondary battery calculated based on the voltage fluctuation becomes zero, is greater than a threshold value, in a state where the measurement unit is switched to the second mode by the switching unit.

### BRIEF DESCRIPTION OF THE DRAWINGS

The above and other objects, features and advantages of the present disclosure will become more apparent from the following detailed description made with reference to the accompanying drawings. In the drawings:

FIG. 1 is an electrical diagram of a power supply system;

FIG. 2 is a block diagram of a battery measurement unit and a battery control ECU;

FIG. 3 is a time chart showing an example of measurement mode switching;

FIG. 4 is a diagram showing each measurement mode;

FIG. 5 is a graph showing a complex impedance plane plot and zero crossing points;

FIG. 6 is a graph showing a relationship between time and a real part of the zero crossing point during thermal runaway;

FIG. 7 is a graph showing a relationship between time and a rate of change of the real part of the zero crossing point during thermal runaway;

FIG. 8 is a flowchart showing a control process for notifying a sign of thermal runaway of a battery cell;

FIG. 9 is a graph showing a relationship between time, the rate of change of the real part of the zero crossing point, and temperature during thermal runaway of a battery cell with a capacity of 25 Ah;

FIG. 10 is a graph showing a relationship between time, the rate of change of the real part of the zero crossing point, and temperature during thermal runaway of a battery cell with a capacity of 50 Ah;

FIG. 11 is a graph showing a relationship between time, the rate of change of the real part of the zero crossing point, and temperature during thermal runaway of a battery cell with a capacity of 150 Ah;

FIG. 12 is a block diagram of the battery measurement unit according to a modified example;

FIG. 13 is a block diagram of the battery measurement unit according to another modified example; and

FIG. 14 is a block diagram of the battery measuring unit according to another modified example.

### DETAILED DESCRIPTION

In an assumable example, a device may measure a complex independence of a secondary battery for multiple frequencies within a measurement range and create a complex impedance plane plot, for example, Cole-Cole plot or Bode plot based on the measurement result to understand the properties of the secondary battery such as an electrode and electrolyte of the second battery.

In a rare situation, a secondary battery may have thermal runaway. As a countermeasure, it is conceivable to detect a sign of thermal runaway of the secondary battery from the acquired characteristics such as an electrode and electrolyte of the secondary battery. The thermal runaway of the secondary battery doe not only occur during the operation of the secondary battery (during charging and discharging), but also may also occur during the stop of the operation of the second battery (not activated and disconnected from the electrical load). For this reason, it is necessary to continuously detect the sign of thermal runaway even when the secondary battery is stopped. In that case, if an attempt is made to grasp the characteristics of the secondary battery by using the method to detect a sign of thermal runaway, there is a risk that a large amount of power will be consumed by the secondary battery.

The present disclosure has been made to solve the above-mentioned problems, and a main object of the present disclosure is to detect a sign of thermal runaway while suppressing power consumption of a secondary battery.

According to a first aspect to address the above-mentioned issue,
a thermal runaway sign detection device for detecting a sign of thermal runaway in a secondary battery includes
a measurement unit that measures a voltage fluctuation in a first mode in which a number of times that a fluctuating current is output from the secondary battery and a voltage fluctuation of the secondary battery in response to the fluctuating current is measured is a first number of times, and in a second mode in which the number of times is a second number of times less than the first number of times,
a switching unit that switches the measurement unit to the second mode when the secondary battery is stopped, and
a detection unit that detects a sign of thermal runaway in the secondary battery when a rate of change in a real part of an AC impedance obtained based on the voltage fluctuation measured by the measurement unit at the fluctuating current of a predetermined frequency at which an imaginary part of the AC impedance of the secondary battery calculated based on the voltage fluctuation becomes zero, is greater than a threshold value, in a state where the measurement unit is switched to the second mode by the switching unit.

According to the above configuration, the measurement unit can measure a voltage fluctuation in a first mode in which a number of times that a fluctuating current is output from the secondary battery and a voltage fluctuation of the secondary battery in response to the fluctuating current is measured is a first number of times, and in a second mode in which the number of times is a second number of times less than the first number of times. When the fluctuating current is output from the secondary battery and the voltage fluctuation of the secondary battery in response to the fluctuating current is measured, a power consumption of the secondary battery can be suppressed more in the second mode than in the first mode. The switching unit switches the measurement unit to the second mode when the secondary battery is stopped (not activated and disconnected from the electrical load). Therefore, even if the voltage fluctuation of the secondary battery is measured while the secondary battery is stopped, the power consumption of the secondary battery can be suppressed.

The real part of the AC impedance calculated using the fluctuating current at a predetermined frequency at which the imaginary part of the AC impedance becomes zero (hereinafter referred to as the “real part of the zero crossing point”) mainly represents a solution resistance, which is a resistance when charges move through a solution (electrolyte) in the secondary battery. The present discloser has focused on a fact that when the secondary battery undergoes the thermal runaway, gasification of the solution occurs and the real part of the zero crossing point increases rapidly.

Therefore, the detection unit detects a sign of thermal runaway in the secondary battery when a rate of change in a real part of an AC impedance obtained based on the voltage fluctuation measured by the measurement unit at the fluctuating current of a predetermined frequency at which an imaginary part of the AC impedance of the secondary battery calculated based on the voltage fluctuation becomes zero, is greater than a threshold value, in a state where the measurement unit is switched to the second mode by the switching unit. Therefore, it is possible to detect that the real part of the zero crossing point begins to increase rapidly due to gasification of the solution as the sign of thermal runaway of the secondary battery. Moreover, there is no need to measure the AC impedance of the secondary battery at multiple frequencies within the measurement range. Since the AC impedance of the secondary battery is measured at the predetermined frequency where the imaginary part of the AC impedance becomes zero, it is possible to further suppress the power consumption of the secondary battery.

The AC impedance of the secondary battery is affected by the temperature and state of charge (SOC) of the secondary battery. For this reason, the real part of the zero crossing point is also affected by the temperature and state of charge of the secondary battery.

In this regard, according to second aspect, the detection unit calculates a rate of change of the real part of the AC impedance based on a converted value obtained by converting the real part of the AC impedance to the real part of the AC impedance when a temperature of the secondary battery is a predetermined temperature and a state of charge of the secondary battery is a predetermined state of charge. With such a configuration, it is possible to accurately detect a sign of thermal runaway in the secondary battery by taking into consideration the effect of the temperature and state of charge of the secondary battery on the real part of the zero crossing point.

According to a third aspect, a magnitude of the fluctuating current output from the secondary battery in the second mode is smaller than a magnitude of the fluctuating current output from the secondary battery in the first mode. With a such configuration, when the fluctuating current is output from the secondary battery and the voltage fluctuation of the secondary battery in response to the fluctuating current is measured, a power consumption of the secondary battery can be further suppressed more in the second mode than in the first mode.

According to a fourth aspect, a calculation unit, when the measurement unit is switched to the second mode by the switching unit, causes the measurement unit to measure the voltage fluctuation at the fluctuating current of the predetermined frequency at predetermined time intervals, and calculates a real part of the AC impedance based on the measured voltage fluctuation. The detection unit calculates a rate of change of the real part of the AC impedance based on the real part of the AC impedance calculated by the calculation unit and the predetermined time, and the calculation unit shortens the predetermined time as the temperature of the secondary battery increases. With such a configuration, the higher the temperature of the secondary battery, the shorter the time interval at which the AC impedance is measured by the measuring unit. Therefore, it is possible to detect the sign of thermal runaway in advance as the possibility of having thermal runaway in the secondary battery is relatively high.

According to a fifth aspect,
a method for detecting a sign of thermal runaway in a secondary battery includes
a measurement step of measuring a voltage fluctuation, in a first mode in which a number of times that a fluctuating current is output from the secondary battery and a voltage fluctuation of the secondary battery in response to the fluctuating current is measured is a first number of times and in a second mode in which the number of times is a second number of times less than the first number of times, by switching to the second mode when the secondary battery is stopped, and
a detection step of detecting a sign of thermal runaway in the secondary battery when a rate of change in a real part of an AC impedance obtained based on the voltage fluctuation measured at the fluctuating current of a predetermined frequency at which an imaginary part of the AC impedance of the secondary battery calculated based on the voltage fluctuation becomes zero, is greater than a threshold value, in a state switched to the second mode.

With the above step, the measurement step measures a voltage fluctuation, in a first mode in which a number of times that a fluctuating current is output from the secondary battery and a voltage fluctuation of the secondary battery in response to the fluctuating current is measured is a first number of times and in a second mode in which the number of times is a second number of times less than the first number of times by switching to the second mode when the secondary battery is stopped. When the fluctuating current is output from the secondary battery and the voltage fluctuation of the secondary battery in response to the fluctuating current is measured, a power consumption of the secondary battery can be suppressed more in the second mode than in the first mode. In the measurement step, when the secondary battery is stopped, the measurement step switches to the second mode. Therefore, even if the voltage fluctuation of the secondary battery is measured while the secondary battery is stopped, the power consumption of the secondary battery can be suppressed.

The real part of the AC impedance calculated using the fluctuating current at a predetermined frequency at which the imaginary part of the AC impedance becomes zero (real part of a zero crossing point) mainly represents a solution resistance, which is a resistance when charges move through a solution in the secondary battery. The present discloser has focused on a fact that when the secondary battery undergoes the thermal runaway, gasification of the solution occurs and the real part of the zero crossing point increases rapidly.

Therefore, the detection step detects a sign of thermal runaway in the secondary battery when a rate of change in a real part of an AC impedance obtained based on the voltage fluctuation measured at the fluctuating current of a predetermined frequency at which an imaginary part of the AC impedance of the secondary battery calculated based on the voltage fluctuation becomes zero, is greater than a threshold value, in a state switched to the second mode. Therefore, it is possible to detect that the real part of the zero crossing point begins to increase rapidly due to gasification of the solution as the sign of thermal runaway of the secondary battery. Moreover, there is no need to measure the AC impedance of the secondary battery at multiple frequencies within the measurement range. Since the AC impedance of the secondary battery is measured at the predetermined frequency where the imaginary part of the AC impedance becomes zero, it is possible to further suppress the power consumption of the secondary battery.

Hereinafter, an embodiment in which a “detection device for detecting a sign of thermal runaway of secondary battery” is applied to a power supply system of a vehicle (for example, a hybrid vehicle or an electric vehicle) will be described with reference to the drawings.

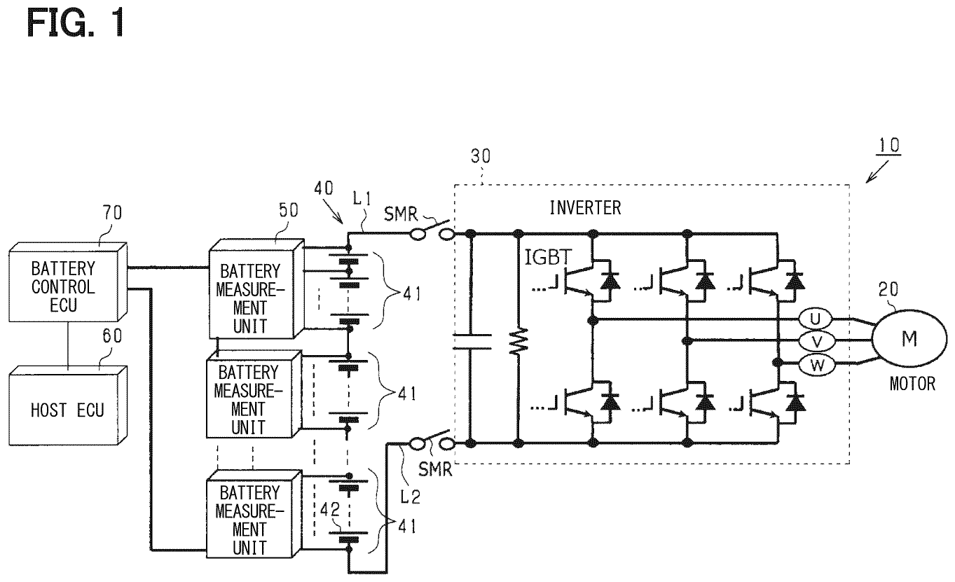

As shown in FIG. 1, a power supply system 10 includes a motor 20 as a rotating electrical machine, an inverter 30 as a power converter for supplying a three-phase current to the motor 20, a rechargeable battery pack 40, a battery measurement unit 50 for measuring the state of the battery pack 40, a battery control ECU 70 for controlling the battery pack 40, and a host ECU 60 for controlling, for example, the motor 20.

The motor 20 (motor generator) is a main machine adapted to the vehicle, and is capable of transmitting power to drive wheels (not shown). In the present embodiment, a three-phase permanent magnet synchronous motor is used as the motor 20. The inverter 30 includes a full bridge circuit having the same number of upper and lower arms as the number of phase windings, and a current supplied to each phase winding is adjusted by turning on and off the switches provided in each arm. A semiconductor switching element is an example of the switch. For example, an IGBT (Insulated Gate Bipolar Transistor) may be adopted as the switch.

The inverter 30 is provided with an inverter controller (not shown), and the inverter controller controls energization by turning on and off each switch in the inverter 30 based on various detection information in the motor 20 or a request for power running and power generation. As a result, the inverter controller supplies electric power from the battery pack 40 to the motor 20 via the inverter 30 to drive the motor 20 in power running mode. In addition, the inverter controller causes the motor 20 to generate power based on the power from the drive wheels, converts the generated power via the inverter 30 and then supplies it to the battery pack 40 to charge the battery pack 40.

The battery pack 40 is electrically connected to the motor 20 via the inverter 30. The battery pack 40 has a terminal voltage of, for example, 100 [V] or more. In the battery pack 40, multiple battery modules 41 are connected in series. In the battery module 41, multiple battery cells 42 are connected in series. As the battery cell 42 being the secondary battery, for example, a lithium iron phosphate (LFP) battery, a lithium ion storage battery, or a nickel metal hydride storage battery can be used. Each battery cell 42 is a storage battery having an electrolytic solution being solution made of electrolyte and solvent and multiple electrodes.

As shown in FIG. 1, a positive terminal of an electrical load such as the inverter 30 is connected to a positive power supply path L1 connected to a positive power supply terminal of the battery pack 40. Similarly, a negative terminal of an electrical load such as the inverter 30 is connected to a negative power supply path L2 connected to a negative power supply terminal of the battery pack 40. A relay switch SMR, in other words, a system main relay switch is provided in each of the positive power supply path L1 and the negative power supply path L2. It is possible to perform energization or de-energization through the relay switch SMR.

The battery measurement unit 50 corresponding to the measurement unit is a device that measures, for example, the state of charge (SOC) and state of health (SOH) of each battery cell 42. The battery measurement unit 50 is connected to the battery control ECU 70, measures the complex impedance of each battery cell 42, and outputs the result. The complex impedance may also be referred to as an impedance of each battery cell 42. The battery measurement unit 50 can measure the complex impedance, in other words, AC impedance of each battery cell 42 in multiple measurement modes with different measurement conditions. The following describes the configuration of the battery measurement unit 50.

The battery control ECU 70 (switching unit, detection unit) controls the battery measurement unit 50 to measure the complex impedance of each battery cell 42 according to the selected (switched) measurement mode. The battery control ECU 70 includes a mode switching unit 71 and a TR (Thermal Runaway) detection unit 72. The following describes the mode switching unit 71 and the TR detection unit 72. The battery measurement unit 50 and the battery control ECU 70 are included in the detection device for detecting the sign of thermal runaway of the secondary battery.

The host ECU 60 requests the inverter controller for power running and power generation based on various information. The various information includes, for example, accelerator and brake operation information, vehicle speed and the state of the battery pack 40. The host ECU 60 also receives the measurement result of the state of each battery cell 42 from the battery control ECU 70.

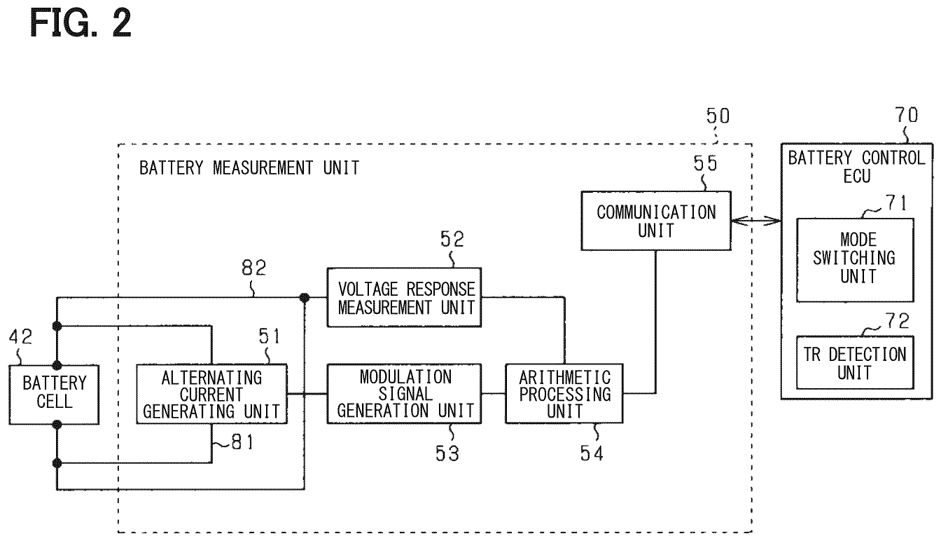

The following describes the battery measurement unit 50 and the battery control ECU 70. As shown in FIG. 2, the battery measurement unit 50 is provided so as to be able to measure the battery state of each battery cell 42. The battery measurement unit 50 includes an AC current generating unit 51 connected to each battery cell 42 via a first electrical path 81, a voltage response measurement unit 52 connected to each battery cell 42 via a second electrical path 82, a modulation signal generator 53 connected to the AC current generating unit 51, an arithmetic processing unit 54 connected to the voltage response measurement unit 52 and the modulation signal generator 53, and a communication unit 55 connected to the arithmetic processing unit 54.

The AC generating unit 51 outputs an alternating current using the battery cell 42 to be measured as a power supply. The AC generating unit 51 corresponds to a current generator or a current generating unit. The alternating current corresponds to a fluctuating current. The AC generating unit 51 controls the battery cell 42 to output the alternating current based on an instruction signal received from the modulation signal generator 53. When the alternating current flows from the battery cell 42, a response signal reflecting complex impedance information is generated in the voltage across the terminals of the battery cell 42. The response signal corresponds to a voltage change or a voltage fluctuation. The voltage response measurement unit 52 measures the response signal reflecting information of the complex impedance of the battery cell 42 between the terminals of the battery cell 42. The response signal corresponds to a voltage change or a voltage fluctuation.

The modulation signal generator 53 has an oscillator that generates an AC signal with an arbitrary waveform. Then, the modulation signal generator 53 causes the oscillator to generate the AC signal according to the instruction from the arithmetic processing unit 54.

Although the AC signal according to the present embodiment is a sine wave signal, the signal may be changed arbitrarily as long as it is an AC signal, and may be, for example, a rectangular wave or a triangular wave signal. In addition, a direct current (DC) bias is applied to the AC signal so that the AC current, in other words, a fluctuating current flowing from the battery cell 42 does not become a negative current, in other words, a reverse current to the battery cell 42.

The modulation signal generator 53 subsequently converts the AC signal into a digital signal to generate an instruction signal, and instructs (outputs) the AC generating unit 51 to generate the alternating current based on the instruction signal.

The arithmetic processing unit 54 includes a microcomputer including a CPU and a storage device, and implements various functions by executing programs stored in the storage device. The CPU corresponds to an arithmetic unit, and a storage device corresponds to various types of memory. Various functions may be implemented by an electronic circuit that is hardware, or may be implemented by both hardware and software.

The arithmetic processing unit 54 has a function of calculating the complex impedance of the battery cell 42. The arithmetic processing unit 54 corresponds to a calculation unit or a calculator. The following describes a method for calculating the complex impedance. The arithmetic processing unit 54 instructs the modulation signal generator 53 about the measurement frequency of the complex impedance. The modulation signal generator 53 causes the battery cell 42 to generate the alternating current corresponding to the fluctuating current via the AC generating unit 51 based on the instruction from the arithmetic processing unit 54. The voltage response measurement unit 52 measures the voltage between the terminals of the battery cell 42, measures a response signal corresponding to voltage fluctuation in response to the input signal corresponding to the alternating current, and outputs the measured response signal to the arithmetic processing unit 54.

The arithmetic processing unit 54 calculates information related to the complex impedance of the battery cell 42 based on the response signal. The arithmetic processing unit 54 repeats the series of processes until complex impedances are calculated for multiple predetermined measurement frequencies within the measurement range. Additionally, the arithmetic processing unit 54 notifies the battery control ECU 70 of the calculation result. The battery control ECU 70 creates, for example, a complex impedance plane plot, in other words, a Cole-Cole plot based on the calculation result, and acquires the characteristics of, for example, the electrode and the electrolyte. Also, the state of charge (SOC) and the state of health (SOH) are grasped.

However, it is not necessary to create the entire Cole-Cole plot, and attention may be paid to a part of the Cole-Cole part. For example, while the vehicle is running, the complex impedance at a specific frequency may be measured at regular time intervals, and changes in the SOC, SOH, battery temperature, and the like while the vehicle is running may be acquired based on the time change in the complex impedance at the specific frequency. Alternatively, the complex impedance at a specific frequency may be measured at time intervals such as every day, every week, or every year, and a change in SOH or the like may be acquired based on a change in the complex impedance over time at the specific frequency. The complex impedance plane plot is not limited to the Cole-Cole plot. For example, a Bode plot can also be used.

In order to ensure the measurement precision of the complex impedance, it is necessary to average the measured values of voltage fluctuations into integrated values to suppress errors. For each AC signal at the measurement frequency, a wavenumber to some extent is output and it is necessary to measure the voltage fluctuation during this period. In other words, when the requested precision is predetermined, it is necessary to output the AC signal with a wave number according to the precision. Here, if the measurement frequency differs, the wave number per unit time also differs. Therefore, if the measurement frequency is a low frequency, it will be necessary to output the alternating current for a longer period of time as compared with a situation in which the measurement frequency is a high frequency. That is, the required output period differs for each measurement frequency.

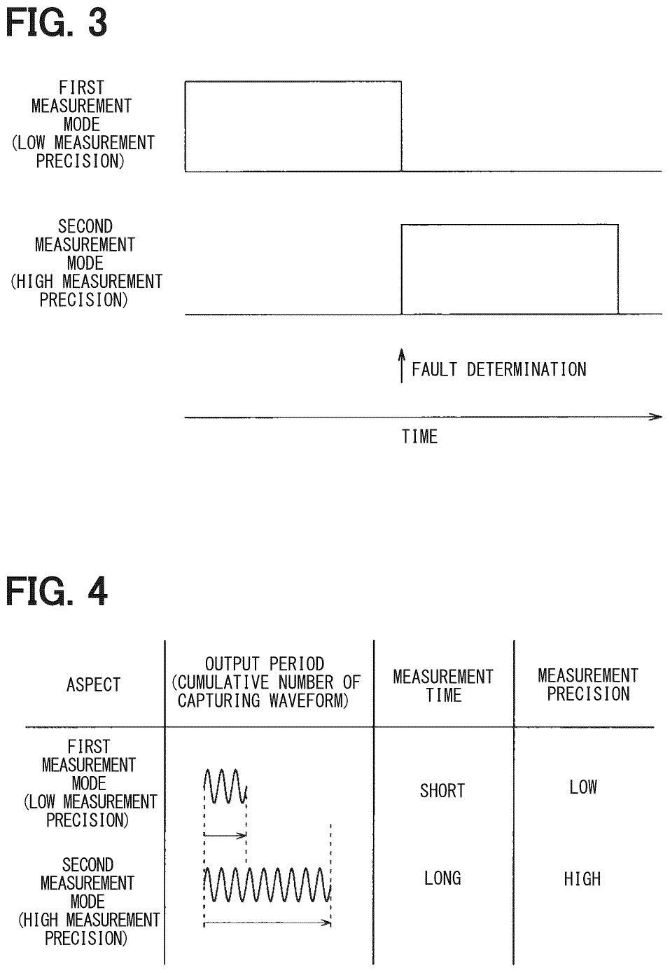

For example, as shown in FIG. 3, the battery control ECU 70 measures the complex impedance in the first measurement mode in which the measurement accuracy is low in a normal state, and determines that the battery cell 42 has a fault based on the measurement result. Then, the complex impedance is measured by switching to the second measurement mode being higher in the measurement precision than the first measurement mode. That is, the complex impedance is normally measured in the first measurement mode with low measurement precision, and when it is determined that the battery cell 42 has a fault, the complex impedance is measured in the second measurement mode in detail. The complex impedance corresponds to a correlation parameter. The first measurement mode corresponds to a second mode. The second measurement mode corresponds to a first mode. The timing for measuring the complex impedance in the first measurement mode is arbitrary. For example, the complex impedance is measured in the first measurement mode periodically. Further, the complex impedance may be measured in the second measurement mode immediately after the battery cell 42 is determined to have a fault in the first measurement mode, or the complex impedance may be measured in the second measurement mode after the elapse of a predetermined time from a situation in which the battery cell 42 is determined to have a fault.

Specifically, the arithmetic processing unit 54 determines the output period of the AC signal based on the set measurement frequency. The output period is a period until the wave number of the AC signal is output with a predetermined number of times, and is calculated based on the measurement frequency. The predetermined number of times indicating the number of times of the wave number is determined in advance according to the required measurement precision. For example, as shown in FIG. 4, the predetermined number of times is 3 in the first measurement mode, and 9 in the second measurement mode. The predetermined number of times in the first measurement mode corresponds to a second number of times, and the predetermined number of times in the second measurement mode corresponds to a first number of times. The predetermined number of times in the second measurement mode is greater than the predetermined number of times in the first measurement mode. The number of times of outputting the AC current through the AC generating unit 51 and measuring the voltage fluctuation of the battery cell 42 through the voltage response measurement unit 52 differs in the first measurement mode and the second measurement mode. In other words, the method of measuring the complex impedance differs between the first measurement mode and the second measurement mode. Therefore, the measurement time in the second measurement mode is longer than the measurement time in the first measurement mode. The measurement precision in the second measurement mode is higher than the measurement precision in the first measurement mode. The power consumption of the battery cell 42 in the first measurement mode is less than the power consumption of the battery cell 42 in the second measurement mode.

Next, the arithmetic processing unit 54 subsequently instructs the modulation signal generator 53 about the set measurement frequency. The modulation signal generator 53 sets the frequency of the AC signal to be output to the oscillator according to the instructed measurement frequency. Then, the oscillator of the modulation signal generator 53 generates the AC signal according to the set measurement frequency. The modulation signal generator 53 converts the analog signal of the generated AC signal into a digital signal, and outputs an instruction signal for outputting the AC signal to the AC generating unit 51.

The AC generating unit 51 provides the alternating current as an input signal to the battery cell 42 based on the instruction signal, and causes the battery cell 42 to output the alternating current being the fluctuating current. The voltage response measurement unit 52 measures the voltage between the terminals of the battery cell 42, measures a response signal corresponding to voltage fluctuation in response to the input signal corresponding to the alternating current, and converts the analog value of the measured response signal to the digital value and then output the converted digital value to the arithmetic processing unit 54. The AC generating unit 51 may provide the alternating current being the fluctuating current to the battery cell 42 or may vary the load on the battery cell 42.

The arithmetic processing unit 54 calculates information related to the complex impedance of the battery cell 42 based on the alternating current and voltage fluctuation. Specifically, the arithmetic processing unit 54 acquires the measured value of the alternating current. In other words, the alternating current flowing through a first electrical path 81 is measured, and the measured alternating current is analyzed according to the frequency of each AC signal as the measurement frequency. Each AC signal as a measurement signal actually flowing through the first electrical path 81 is extracted and obtained.

The arithmetic processing unit 54 subsequently analyzes the response signal based on the acquired AC signal, and calculates a value proportional to the real part and a value proportional to the imaginary part of the response signal as the information related to the complex impedance. The value proportional to the real part and the value proportional to the imaginary part of the response signal are average values, in other words, integrated values from the start of outputting each AC signal.

Next, the arithmetic processing unit 54 determines whether or not the output period of the AC signal according to each measurement mode has ended. In the first measurement mode, the output period is a period until three AC signals are output. In the second measurement mode, the output period is a period until nine AC signals are output. When the determination result is negative, the calculation processing unit 54 continues the measurement and calculation. On the other hand, when the determination result is affirmative, the arithmetic processing unit 54 stops the generation of the AC signal.

The arithmetic processing unit 54 acquires the values proportional to the real part and the imaginary part of the response signal corresponding to the AC signal, and calculates all or any of the absolute values and the phases of the complex impedance at the measurement frequency of the AC signal based on the acquired values. Then, the arithmetic processing unit 54 notifies the battery control ECU 70 of the calculated complex impedance.

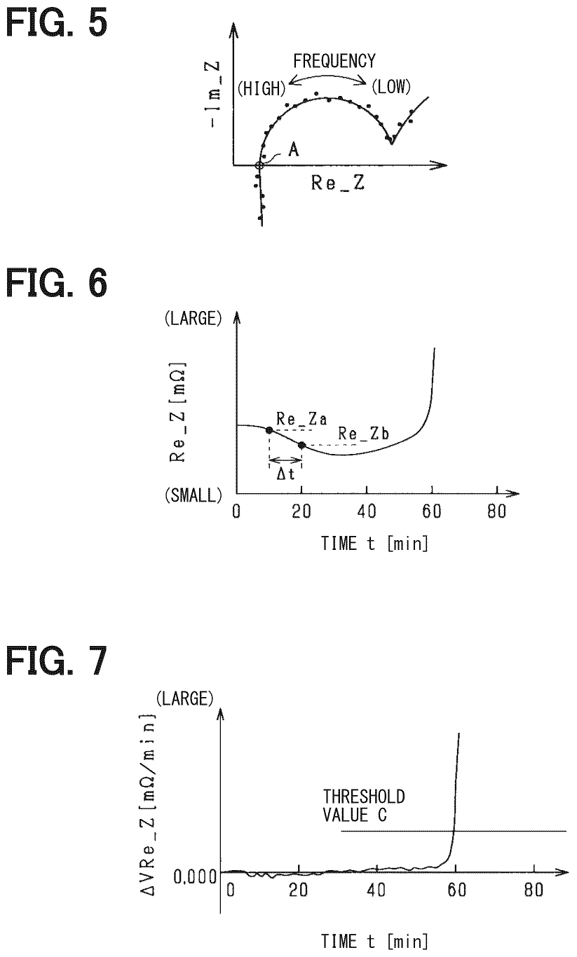

FIG. 5 is a graph showing a complex impedance plane plot and a zero crossing point. The zero crossing point may also be simply referred to as a zero crossing. The battery measurement unit 50 periodically measures the complex impedance of the battery cell 42 while changing the measurement frequency at the time during which the vehicle equipped with the power supply system 10 is running (in other words, the battery pack 40 is operating), and then creates the complex impedance plane plot. The horizontal axis represents the real part of the complex impedance, and the vertical axis represents the imaginary part of the complex impedance. The zero crossing is a point where the complex impedance graph intersects the horizontal axis, that is, the point where the imaginary part of the complex impedance becomes zero.

Black dots in the figure represent complex impedance measurements over a wide range of frequencies from low to high frequencies. The diameter of the real part of the arc mainly represents a reaction resistance being a resistance when the molecule exits the electrode into the solution (electrolyte) in the battery cell 42. The real part at the zero crossing point A indicated by a white circle mainly represents a solution resistance being a resistance when charges move in the solution in the battery cell 42. The discloser of the present application has noticed that, when the battery cells 42, in other words, the battery module 41 and the battery pack 40 undergo thermal runaway, gasification of the solution occurs and the real part of the zero crossing point A rapidly increases.

FIG. 6 is a graph showing the relationship between the time t and the real part Re_Z of the zero crossing point during thermal runaway of the battery cell 42. Before the thermal runaway of the battery cell 42 occurs, the real part Re_Z [mΩ] of the zero crossing point becomes, for example, Re_Za [m (2] or Re_Zb [mΩ], and hardly changes. Then, when the battery cell 42 has thermal runaway, the real part Re_Z of the zero crossing point increases rapidly. The real parts Re_Za and Re_Zb of the zero crossing point are conversion values acquired by converting the real part Re_Z of the zero crossing point calculated at the present temperature and the present SOC of the battery cell 42 to the real part of the zero crossing point in a case where: the temperature T of the battery cell 42 is a predetermined temperature; and the SOC of the battery cell 42 is predetermined state of charge (SOC). The reason for converting the real part Re_Z of the zero crossing point to the conversion value is that the complex impedance of the battery cell 42 is affected by the temperature T and SOC of the battery cell 42 and the real part of the zero crossing point is also affected by the temperature T and SOC of the battery cell 42.

FIG. 7 is a graph showing the relationship between the time t during the thermal runaway of the battery cell 42 and a rate of change ΔVRe_Z of the real part Re_Z of the zero crossing point. The rate of change ΔVRe_Z of the real part Re_Z of the zero crossing point can be calculated by dividing the amount of change ΔRe_Z of the real part Re_Z of the zero crossing point by the time Δt required for the change (ΔVRe_Z=ΔRe_Z/At). For example, when the real part Re_Z [mΩ] of the zero crossing point changes from Re_Za [mΩ] to Re_Zb [mΩ] in time Δt [min], the rate of change ΔVRe_Z [mΩ/min] in the real part Re_Z of the zero crossing point=(Re_Zb-Re_Za)/At. When the battery cell 42 has thermal runaway, the rate of change ΔVRe_Z in the real part Re_Z of the zero crossing point increases rapidly in the previous stage. That is, as a sign of thermal runaway of the battery cells 42, in other words, the battery module 41 and the battery pack 40, the rate of change ΔVRe_Z in the real part Re_Z at the zero cross point is rapidly increasing. In the present embodiment, when the rate of change ΔVRe_Z in the real part Re_Z of the zero crossing point exceeds the threshold value C (in other words, the rate of change ΔVRe_Z is greater than the threshold C), it is detected that there is a sign of thermal runaway in the battery cell 42.

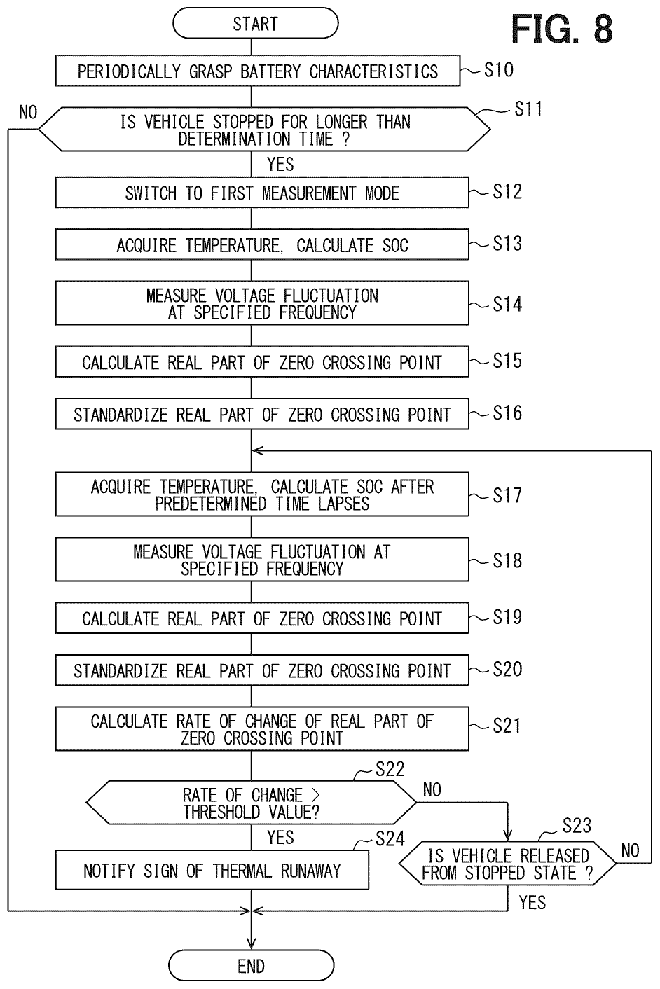

FIG. 8 is a flowchart showing a control process for notifying a sign of thermal runaway of the battery cell 42. This series of processes is executed by the battery measurement unit 50 and the battery control ECU 70.

In S10, the battery control ECU 70 periodically grasps the characteristics of the battery cell 42 based on the information related to the complex impedance of the battery cell 42 measured by the battery measurement unit 50. For example, the battery control ECU 70 periodically measures the complex impedance in the first measurement mode set by the battery measurement unit 50. When it is determined that the battery cell 42 has a fault based on the measurement result, the battery measurement unit 50 switches from the first measurement mode to the second measurement mode to that the battery control ECU 70 measures the complex impedance in the second measurement mode. Then, the battery control ECU 70 creates a complex impedance plane plot based on the measured complex impedance, and grasps the characteristics of the electrodes and the electrolyte as well as the state of charge (SOC) or the state of health (SOH).

Next, the battery control ECU 70 determines whether the vehicle equipped with the power supply system 10 has been stopped for a period exceeding a determination time ts in S11. Specifically, the battery control ECU 70 determines whether the vehicle equipped with the power supply system 10 has been parked for, for example, more than 3 hours (determination time), i.e., whether the battery pack 40 is stopped (not activated and disconnected from the electrical load). The fact that the battery pack 40 is stopped can be determined, for example, by the power supply system 10 (vehicle) being in a sleep mode, the relay switch SMR being turned off (shut off), etc. Even if the power supply system 10 is in the sleep mode, the battery control ECU 70 can execute a determination, which means a minimum processing, as to whether or not the vehicle has been stopped for a period exceeding the determination time ts. In the case where it is determined that the vehicle equipped with the power supply system 10 has not been stopped for the determination time ts or longer (S11: NO), this series of processes ends, namely, the process proceeds to END.

On the other hand, when it is determined in the determination of S11 that the vehicle equipped with the power supply system 10 has been stopped for longer than the determination time ts (S11: YES), the battery control ECU 70 switches the measurement mode of the battery measurement unit 50 to the first measurement mode (second mode) in S12. The battery measurement mode 50 acquires the temperature T of the battery cell 42, and calculates the SOC of the battery cell 42 in S13. The temperature T of the battery cell 42 can be acquired, for example, based on the output of, for example, a thermistor attached to the battery cell 42, in other words, the battery module 41 and the battery pack 40. The SOC of the battery cell 42 can be calculated based on, for example, the SOC at a predetermined time and the integrated value of the current flowing through the battery cell 42 after the predetermined time.

Subsequently, the battery measurement unit 50 causes the battery cell 42 to output the alternating current, in other words, the fluctuating current with a predetermined frequency, and measures the voltage fluctuation of the battery cell 42 in response to the alternating current in S14. The predetermined frequency is the measurement frequency at which the imaginary part of the complex impedance of the battery cell 42 calculated based on the voltage fluctuation of the battery cell 42 is 0. In other words, the predetermined frequency is at which the graph of the complex impedance intersects the horizontal axis. For example, the predetermined frequency is the measurement frequency at the zero crossing point A in the Cole-Cole plot as illustrated in FIG. 5. It is possible to calculate the predetermined frequency based on, for example, an experiment adopting the battery cell 42. The measurement of the voltage fluctuation is performed in a state in which the battery measurement unit 50 has been switched to the first measurement mode in the process of S12.

Subsequently, the battery measurement unit 50 calculates the real part of the zero crossing point based on the alternating current and voltage fluctuation in S15. The method of calculating the real part of the zero crossing point is the same as the method of calculating information about the complex impedance of the battery cell 42 based on the alternating current and voltage fluctuation, as described above.

Next, the battery control ECU 70 standardizes the real part of the calculated zero crossing point in S16. Specifically, the battery control ECU 70 calculates a conversion value acquired by converting the real part of the zero crossing point calculated by the battery measurement unit 50 to the real part of the zero crossing point in a situation where the temperature T of the battery cell 42 is a predetermined temperature and the SOC of the battery cell 42 is a predetermined SOC (predetermined state of charge). This conversion value can be calculated by applying the temperature T of the battery cell 42 and the SOC of the battery cell 42 acquired in S13 to a map or formula that defines the relationship among, for example, the temperature T of the battery cell 42, the SOC of the battery cell 42 and the real part of the zero crossing point. For example, 25 [° C.] can be used as the predetermined temperature, and 90 [%] can be used as the predetermined SOC. The map and formula can be calculated in advance based on an experiment in which, for example, the battery cell 42 is adopted.

Subsequently, the battery measurement unit 50 acquires the temperature T of the battery cell 42 and calculates the SOC of the battery cell 42 in S17, after a predetermined time Δt has elapsed since the last time an AC current of a predetermined frequency was output from the battery cell 42 and the voltage fluctuation of the battery cell 42 was measured. This process is executed after waiting until a predetermined time Δt has elapsed since the previous time an AC current of a predetermined frequency was output from the battery cell 42 and the voltage fluctuation of the battery cell 42 was measured. That is, on the condition that a predetermined time Δt has elapsed since the previous time an AC current of a predetermined frequency was output from the battery cell 42 and the voltage fluctuation of the battery cell 42 was measured, the battery measurement unit 50 acquires the temperature T of the battery cell 42, calculates the SOC of the battery cell 42, and executes the processes from S18 onwards. The predetermined time Δt is, for example, 1 to 5 [min]. The process of acquiring the temperature T of the battery cell 42 and the process of calculating the SOC of the battery cell 42 are the same as the process in S13. The predetermined time Δt may be a time elapsed from a situation where the temperature T of the battery cell 42 was obtained in the previous occasion and the SOC of the battery cell 42 was calculated.

The processes in S18 to S20 are the same as processes in S14 to S16.

Next, the battery control ECU 70 calculates the rate of change of the real part of the zero crossing point in S21. For example, the amount of change ΔRe_Z (difference in conversion value) from the conversion value Re_Za of the real part of the zero crossing point calculated last occasion to the conversion value Re_Zb of the real part of the zero crossing point calculated after a predetermined time Δt is divided by the predetermined time Δt. Then, the rate of change ΔVRe_Z in the real part of the zero crossing point is calculated (ΔVRe_Z=ΔRe_Z/At).

Subsequently, the battery control ECU 70 determines whether or not the rate of change ΔVRe_Z of the real part of the zero crossing point is greater than the threshold value C in S22. When it is determined in this determination that the rate of change ΔVRe_Z of the real part of the zero crossing point is not greater than the threshold value C (S22: NO), the battery control ECU 70 determines whether the vehicle equipped with the power supply system 10 has been released from a stopped state in S23. The fact that the vehicle equipped with the power supply system 10 has been released from the stopped state can be determined, for example, by the sleep mode of the power supply system 10 (vehicle) being released, the relay switch SMR being turned on (connected), etc. In the case where it is determined that the vehicle equipped with the power supply system 10 has not been released from the stopped state (S23: NO), the processes from S17 are executed again. On the other hand, when it is determined in S23 that the vehicle equipped with the power supply system 10 has been released from the stopped state (S23: YES), this series of processes proceeds to END.

Furthermore, in the determination executed in S22, in a case where the rate of change ΔVRe_Z in the real part of the zero crossing point is greater than the threshold value C (S22: YES), the battery control ECU 70 notifies the host ECU 60 of the sign of thermal runaway in the battery cell 42 in S24. That is, the battery control ECU 70 detects that there is a sign of thermal runaway in the battery cell 42 and notifies the host ECU 60 of the sign of thermal runaway, that is, a fault in the battery cell 42 through communication. Upon receiving the notification, the host ECU 60 notifies a driver of the vehicle of the fault by, for example, an alarm. The host ECU 60 may receive the notification and notify, for example, a monitor center capable of executing communication with the vehicle of the fault. Then, the series of processes described above is terminated in END.

The processes of S11 and S12 correspond to the processes as the mode switching unit 71 (switching unit), the processes of S14 and S18 correspond to the processes as the measurement unit, the processes of S13 to S20 correspond to the processes (calculation step) as the arithmetic processing unit 54 (calculation unit), and the processes of S21, S22, and S24 correspond to the processes (detection step) as the TR detection unit 72 (detection unit). The processes of S11, S12, S14, and S18 correspond to the measurement step.

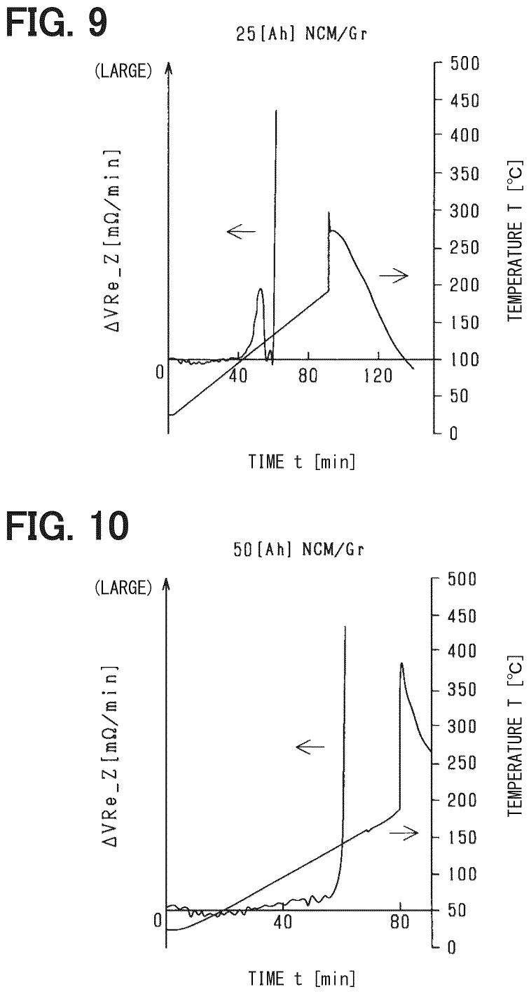

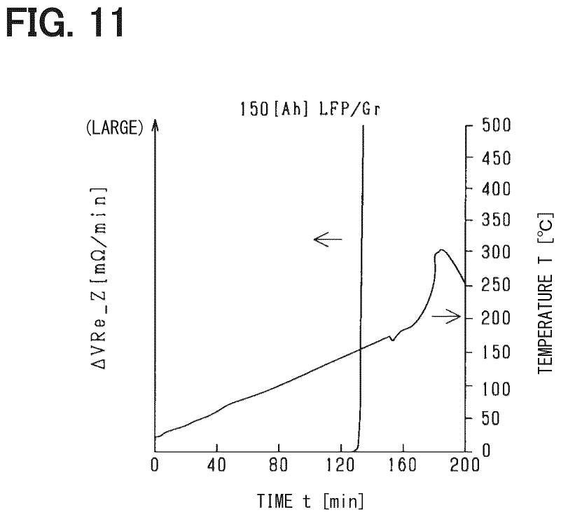

Each of the graphs in FIGS. 9 to 11 illustrates the relationship among the time t, the rate of change ΔVRe_Z (left axis) in the real part of the zero crossing point, and the temperature T (right axis) during thermal runaway of battery cells with different capacities. The SOC of each battery cell is adjusted to 90 [%], and the temperature of each battery cell is simulated to rise at a constant rate. FIG. 9 illustrates a battery cell having a capacity of 25 [Ah], a positive electrode made of nickel-based material NCM (nickel, cobalt, aluminum, manganese) and a negative electrode made of graphite (Gr). FIG. 10 illustrates a battery cell having a capacity of 50 [Ah], a positive electrode made of nickel-based material NCM, and a negative electrode made of Gr. FIG. 11 illustrates a battery cell having a capacity of 150 [Ah], a positive electrode of lithium, iron, phosphorus and a negative electrode of Gr.

The predetermined frequency at which the imaginary part of the complex impedance of the battery cell 42 becomes 0, that is, the measurement frequency at which the complex impedance graph intersects the horizontal axis, differs depending on the capacity of each battery cell. For example, the predetermined frequency of the battery cell in FIG. 9 is 400 [Hz]. The predetermined frequency of the battery cell in FIG. 10 is 250 [Hz]. The predetermined frequency of the battery cell in FIG. 11 is 120 [Hz]. Thus, the predetermined frequency tends to decrease as the capacity of the battery cell increases. Although there is such a difference in the predetermined frequency, in any of FIGS. 9 to 11, the rate of change ΔVRe_Z in the real part of the zero crossing point rapidly rises earlier than the time when the battery cell has the thermal runaway and the temperature rapidly rises. Therefore, by monitoring the rate of change ΔVRe_Z in the real part of the zero crossing point, it is possible to detect the sign of the thermal runaway of the battery cell 42 before the thermal runaway occurs. The battery cell in FIG. 9 has a vent valve that discharges the internal gas when the internal pressure becomes abnormally high. When gas is discharged from the vent valve, the rate of change ΔVRe_Z of the real part of the zero crossing point drops once, but the rate of change ΔVRe_Z rises sharply before the battery cell undergoes thermal runaway.

The present embodiment described above in detail has the following advantages.

The modulation signal generator 53, the AC generating unit 51, and the voltage response measurement unit 52 of the battery measurement unit 50 can detect the voltage fluctuations through the second measurement mode and the first measurement mode. The second measurement mode corresponds to a first mode. The first measurement mode corresponds to a second mode. In the second measurement mode, the number of occurrences for causing the battery cell 42 to output the alternating current being a fluctuating current to measure the voltage fluctuations in the battery cell 42 in response to the alternating current is 9 being a first number of occurrences. In contrast, the number of occurrences in the first measurement mode is 3 being a second number of occurrences that is smaller than 9 being the first number of occurrences. When measuring the voltage fluctuation of the battery cell 42 in response to the AC current output from the battery cell 42, the power consumption of the battery cell 42 can be suppressed more in the first measurement mode than in the second measurement mode. The mode switching unit 71 switches the modulation signal generator 53, the AC generating unit 51 and the voltage response measurement unit 52 to the first measurement mode, in a case where the battery cell 42 stops operation. The stoppage of the operation of the battery cell 42 includes a situation where the battery cell 42 is not being activated, or includes a situation where the battery cell 42 is isolated from the electric load. Therefore, even if the voltage of the battery cell 42 is measured while the battery cell 42 stops operation, the power consumption of the battery cell 42 can be suppressed.

The TR detection unit 72 calculates the rate of change ΔVRe_Z in the complex impedance real part Re_Z based on the complex impedance real part Re_Z and the predetermined time Δt calculated by the arithmetic processing unit 54. When the calculated rate of change ΔVRe_Z is greater than the threshold value C, the TR detection unit detects that there is a sign of thermal runaway in the battery cell 42. Therefore, it is possible to detect that the real part Re_Z of the zero crossing point begins to increase rapidly due to gasification of the solution as the sign of thermal runaway of the battery cell 42. Moreover, there is no need to measure the complex impedance of the battery cell 42 at multiple frequencies within the measurement range. Since the complex impedance of the battery cell 42 may be measured at the predetermined frequency where the imaginary part of the complex impedance becomes zero, it is possible to further suppress the power consumption of the battery cell 42. The measurement of the voltage fluctuation of the battery cell 42 can also be performed in a short time. The duration of the short time is acquired by multiplying several to several tens [ms] by the number of waves (number of times).

The TR detection unit 72 calculates the rate of change ΔVRe_Z of the real part Re_Z of the complex impedance based on the conversion values Re_Za and Re_Zb and the predetermined time Δt. The conversion values Re_Za and Re_Zb are acquired by converting the real part Re_Z of the complex impedance calculated by the arithmetic processing unit 54 into the real part of the complex impedance in a case where the temperature T of the battery cell 42 is the predetermined temperature and the state of charge (SOC) of the battery cell 42 is the predetermined state of charge (predetermined SOC). With such a configuration, it is possible to accurately detect the sign of thermal runaway of the battery cell 42 in consideration of the influence of the temperature T and SOC of the battery cell 42 based on the real part Re_Z of the zero crossing point.

The above-described embodiment can be modified as follows in practical application. Elements identical to the elements of the above embodiment are designated by the same reference signs as the above embodiment, and redundant description thereof is omitted.

The host ECU 60 may cause the vehicle to perform an evacuation run when the host ECU 60 receives a notification of the sign of thermal runaway, in other words, a fault in the battery cell 42. The host ECU 60 may unlock the doors of the vehicle when receiving a notification of the sign of thermal runaway in the battery cell 42. This prevents the driver from opening the door of the vehicle in a hurry. Moreover, the battery control ECU 70 may shut down the battery pack 40, in other words, power supply system 10 when detecting the sign of thermal runaway in the battery cell 42. The power supply system 10 may also be adapted to an electric aircraft or an electric watercraft. Since it may be difficult for the driver to escape from the electric aircraft or electric watercraft in the event of a fault, it is important to shut down the battery pack 40.

In the process of S22 in FIG. 8, in addition to determining that the rate of change ΔVRe_Z in the real part of the zero crossing point is greater than the threshold value C (S22: YES), the battery control ECU 70 may notify the host ECU 60 of the sign of thermal runaway in the battery cell 42 based on a condition that the temperature T of the battery cell 42 is higher than the determination temperature (for example, 60[° C.]) in S24. According to such a configuration, it is possible to inhibit erroneous detection of the sign of thermal runaway in the battery cell 42 when the possibility of thermal runaway in the battery cell 42 is low.

The TR detection unit 72 may convert the rate of change in the real part Re_Z of the complex impedance based on the real part Rz_Z of the complex impedance and the predetermined time Δt, without converting the real part Rz_Z of the complex impedance calculated by the arithmetic processing unit 54 to the real part of the complex impedance at the predetermined temperature and the predetermined SOC. The TR detection unit 72 may subsequently detect the sign of thermal runaway in the battery cell 42 in a case where the calculated rate of change ΔVRe_Z is larger than the threshold value C.

In the first measurement mode, in other words, the second mode, the magnitude (amplitude) of the alternating current (fluctuating current) output from the battery cell 42 may be set to be smaller than the magnitude of the alternating current output from the battery cell 42 in the second measurement mode, in other words, the first mode. Specifically, the arithmetic processing unit 54 causes the oscillator in the modulation signal generator 53 to generate the AC signal, such that the alternating current output from the battery cell 42 in the first measurement mode is smaller than the alternating current output from the battery cell 42 in the second measurement mode. The modulation signal generator 53 subsequently converts the AC signal into a digital signal to generate an instruction signal, and instructs (outputs) the AC generating unit 51 to generate the alternating current based on the instruction signal. With such a configuration, when measuring the voltage change of the battery cell 42 in response to the AC current output from the battery cell 42, the power consumption of the battery cell 42 can be suppressed more in the first measurement mode than in the second measurement mode.

The arithmetic processing unit 54 may shorten the predetermined time Δt as the temperature T of the battery cell 42 increases in S17 illustrated in FIG. 8. In other words, the standby time, in other words, the predetermined time Δt elapsed from the previous time when an AC current of a predetermined frequency was output from the battery cell 42 to measure the voltage fluctuation of the battery cell 42, to the time when the temperature T of the battery cell 42 was acquired, the SOC of the battery cell 42 was calculated, and the processes subsequent to S18 is executed may be shortened as the temperature T of the battery cell 42 rises. With such a configuration, the higher the temperature T of the battery cell 42 is, the shorter the time interval at which the complex impedance is measured by the battery measurement unit 50. Therefore, it is possible to detect the sign of thermal runaway in advance as the possibility of having thermal runaway in the battery cell 42 is relatively high.

In the battery measurement unit 50, in other words, the measurement unit may include a third measurement mode, in other words, a third mode, such that the number of occurrences of outputting the alternating current from the AC generating unit 51 and measuring the voltage change of the battery cell 42 through the voltage response measurement unit 52 in the third measurement mode differs from the first measurement mode and the second measurement mode. The first measurement mode corresponds to the second mode, and the second measurement mode corresponds to the first mode.

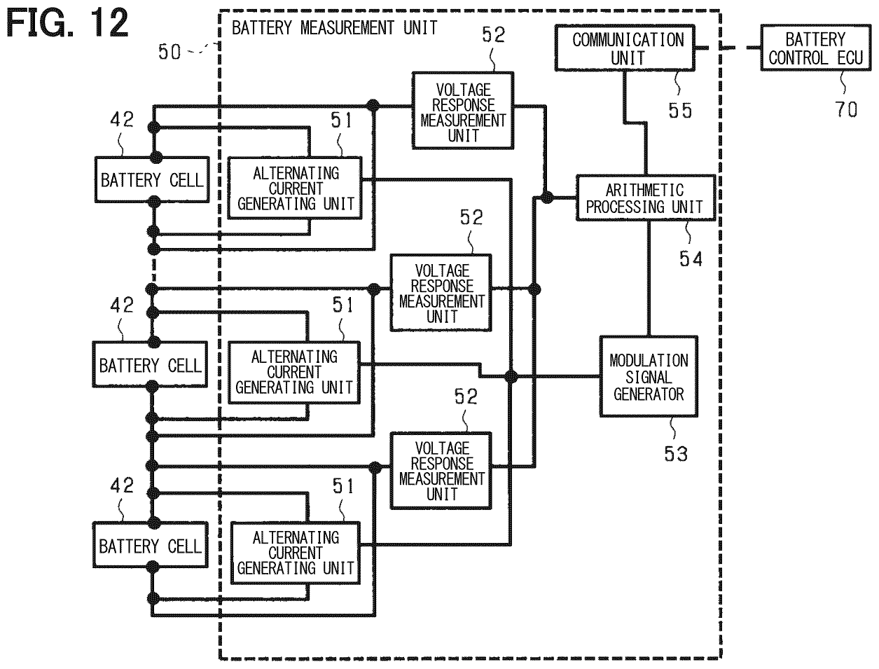

As illustrated in FIG. 12, the battery measurement unit 50 may include the AC generating unit 51 and the voltage response measurement unit 52 for each battery cell 42. When multiple battery cells 42 are set as the measurement targets, in other words, detection targets of the sign of thermal runaway, the alternating current may flow individually in each of the battery cells 42 or the alternating currents may flow in the multiple battery cells 42 at the same time to measure the voltage fluctuation of each of the battery cells 42 with the voltage response measurement unit 52 provided for each of the battery cells 42.

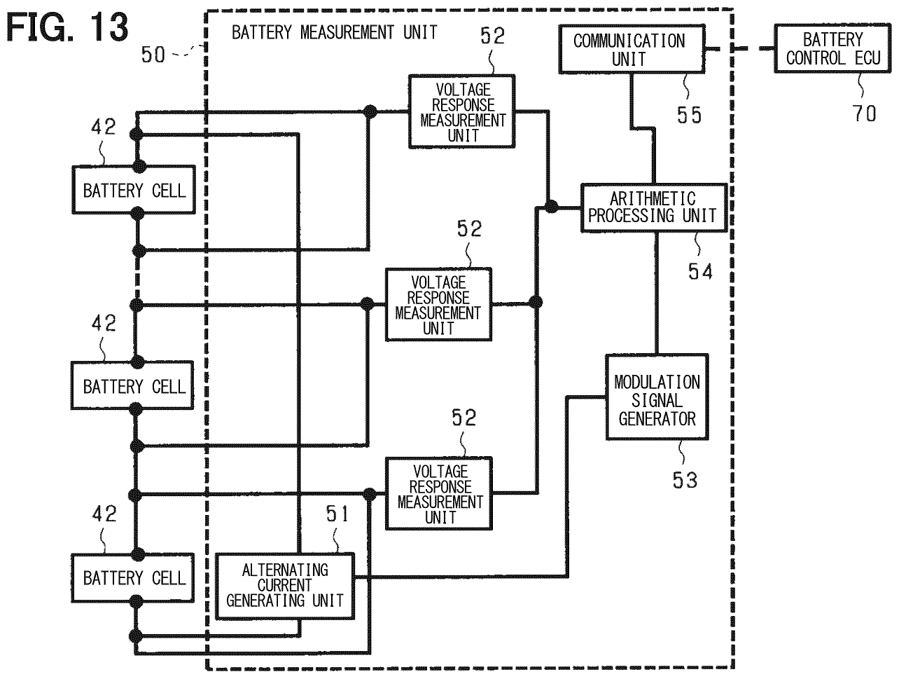

As illustrated in FIG. 13, the battery measurement unit 50 may include a single AC generating unit 51 for multiple battery cells 42, and may include the voltage response measurement unit 42 for each of the battery cells 42. When multiple battery cells 42 are set as the measurement targets, in other words, detection targets of the sign of thermal runaway, the alternating current collectively may flow in the multiple battery cells 42, and the voltage fluctuation of each of the battery cells 42 may be measured through each voltage response measurement unit 52.

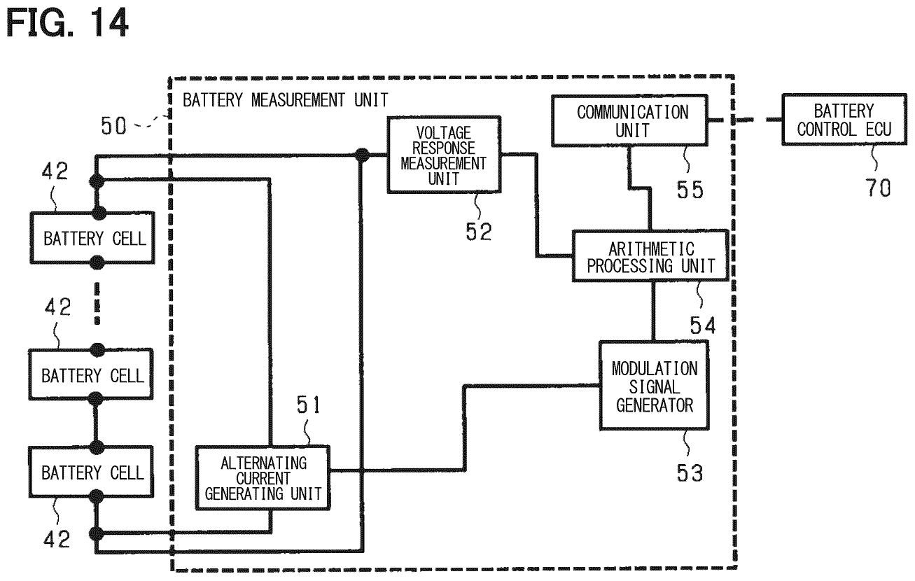

As shown in FIG. 14, the battery measurement unit 50 may include a single AC generating unit 51 and a single voltage response measurement unit 52 for multiple battery cells 42. When multiple battery cells 42 are set as the measurement targets, in other words, detection targets of the sign of thermal runaway, the alternating current collectively may flow in the multiple battery cells 42, and the voltage fluctuation of the multiple battery cells 42 may be collectively measured through the voltage response measurement unit 52.

The alternating current may be passed through the entire battery module 41 to measure the voltage fluctuations of each battery cell 42 (to detect signs of thermal runaway), or the voltage fluctuations of the entire battery module 41 may be measured (to detect signs of thermal runaway). Alternatively, the alternating current may be passed through the entire battery pack 40 and the voltage fluctuation of each battery cell 42 may be measured (to detect signs of thermal runaway), or the voltage fluctuation of the entire battery pack 40 may be measured (to detect signs of thermal runaway).

When the vehicle is stopped for longer than the determination time ts (such as when the ignition is turned off), if the battery control ECU 70 is in the sleep state, the battery measurement unit 50 may start up the battery control ECU 70. The mode switching unit 71 and the TR detection unit 72 may be provided inside the battery measurement unit 50, for example, the arithmetic processing unit 54. In this case, the battery measurement unit 50 is constructed as a detection device for detecting a sign of thermal runaway in the secondary battery. The power supply for the battery control ECU 70 and the battery measurement unit 50 may be the battery pack 40, in other words, the battery module 41 with a high voltage or a lead battery with a low voltage or the like. The AC generating unit 51 can also be provided in, for example, a charger outside the vehicle. In addition, the function of detecting the sign of thermal runaway in the battery measurement unit 50 and the battery control ECU 70 may be adapted to, for example, a vehicle charger, a battery measurement unit and a battery control ECU in an exchangeable battery pack, and a rechargeable energy management system (EMS) in a rechargeable station. The vehicle charger may be, for example, an AC charger, a DC charger, and a vehicle-to-home (V2H) charger.

When the vehicle is stopped for longer than the judgment time ts (e.g., when the ignition is turned off), if the host ECU 60 is in a sleep state, in a case where a diagnostic result other than a thermal runaway symptom is finally detected and a symptom of an abnormality is finally detected, the host ECU 60 may be started to issue an alarm or the like. When the sign of faults with the combination of the sign of thermal runaway and another diagnostic result is finally detected, the power supply of a machine to which a signal for notification of the sign of faults is transmitted can be ensured. In a case of detecting the sign of faults, the process for detecting the sign of thermal runaway may be executed multiple times to ensure the detection of the sign of faults, based on a condition that the sign of thermal runaway has been detected multiple times. As a result, it is possible to inhibit erroneous detection of the sign of faults and erroneous operation of, for example, an alarm.

The modified examples described above may be implemented in combination.

Although the present disclosure has been described in accordance with the embodiments, it is understood that the present disclosure is not limited to the embodiments and structures disclosed therein. The present disclosure encompasses various modifications and variations within the scope of equivalents. In addition, while the various combinations and configurations, which are preferred, other combinations and configurations, including more, less or only a single element, are also within the spirit and scope of the present disclosure.

What is claimed is:

1. A thermal runaway sign detection device for detecting a sign of thermal runaway in a secondary battery, comprising:
a measurement unit configured to measure a voltage fluctuation in a first mode in which a number of times that a fluctuating current is output from the secondary battery and a voltage fluctuation of the secondary battery in response to the fluctuating current is measured is a first number of times, and in a second mode in which the number of times is a second number of times less than the first number of times,
a switching unit configured to switch the measurement unit to the second mode when the secondary battery is stopped, and
a detection unit configured to detect a sign of thermal runaway in the secondary battery when a rate of change in a real part of an AC impedance obtained based on the voltage fluctuation measured by the measurement unit at the fluctuating current of a predetermined frequency at which an imaginary part of the AC impedance of the secondary battery calculated based on the voltage fluctuation becomes zero, is greater than a threshold value, in a state where the measurement unit is switched to the second mode by the switching unit.

2. The thermal runaway sign detection device in the secondary battery according to claim 1, wherein
the detection unit calculates a rate of change of the real part of the AC impedance based on a converted value obtained by converting the real part of the AC impedance to the real part of the AC impedance when a temperature of the secondary battery is a predetermined temperature and a state of charge of the secondary battery is a predetermined state of charge.

3. The thermal runaway sign detection device in the secondary battery according to claim 1, wherein
a magnitude of the fluctuating current output from the secondary battery in the second mode is smaller than a magnitude of the fluctuating current output from the secondary battery in the first mode.

4. The thermal runaway sign detection device in the secondary battery according to claim 1, further comprising,
a calculation unit, when the measurement unit is switched to the second mode by the switching unit, causes the measurement unit to measure the voltage fluctuation at the fluctuating current of the predetermined frequency at predetermined time intervals, and calculates a real part of the AC impedance based on the measured voltage fluctuation, wherein
the detection unit calculates a rate of change of the real part of the AC impedance based on the real part of the AC impedance calculated by the calculation unit and the predetermined time, and
the calculation unit shortens the predetermined time as a temperature of the secondary battery increases.

5. A method for detecting a sign of thermal runaway in a secondary battery, comprising:
a measurement step of measuring a voltage fluctuation, in a first mode in which a number of times that a fluctuating current is output from the secondary battery and a voltage fluctuation of the secondary battery in response to the fluctuating current is measured is a first number of times and in a second mode in which the number of times is a second number of times less than the first number of times, by switching to the second mode when the secondary battery is stopped, and
a detection step of detecting a sign of thermal runaway in the secondary battery when a rate of change in a real part of an AC impedance obtained based on the voltage fluctuation measured at the fluctuating current of a predetermined frequency at which an imaginary part of the AC impedance of the secondary battery calculated based on the voltage fluctuation becomes zero, is greater than a threshold value, in a state switched to the second mode.

6. A thermal runaway sign detection device for detecting a sign of thermal runaway in a secondary battery, comprising:
a computer including a processor and a memory that stores instructions configured to, when executed by the processor, cause the processor to
measure a voltage fluctuation in a first mode in which a number of times that a fluctuating current is output from the secondary battery and a voltage fluctuation of the secondary battery in response to the fluctuating current is measured is a first number of times, and in a second mode in which the number of times is a second number of times less than the first number of times,
switch the measurement unit to the second mode when the secondary battery is stopped, and
detect a sign of thermal runaway in the secondary battery when a rate of change in a real part of an AC impedance obtained based on the voltage fluctuation measured by the measurement unit at the fluctuating current of a predetermined frequency at which an imaginary part of the AC impedance of the secondary battery calculated based on the voltage fluctuation becomes zero, is greater than a threshold value, in a state where the measurement unit is switched to the second mode by the switching unit.
